(19) United States
(12) Patent Application Publication
(10) Pub. No.: US 2006/0163991 A1
(43) Pub. Date: Jul. 27, 2006

(54) Organic light emitting device

(75) Inventors: Shi-Hao Li, Panchiao City (TW); Che-Jen Chen, Kaohsiung City (TW)

Correspondence Address: BIRCH STEWART KOLASCH & BIRCH, PO BOX 747, FALLS CHURCH, VA, 22040-0747, US

(73) Assignee: AU Optronics Corp.

(21) Appl. No.: 11/334,395

(22) Filed: Jan. 19, 2006

(30) Foreign Application Priority Data
Jan. 21, 2005 (TW) 94101891

(51) Int. Cl. H01L 51/52; H05B 33/12

(52) U.S. Cl. 313/113; 428/917; 313/504; 313/506; 257/98

(57) ABSTRACT

An organic light emitting device includes a transparent electrode, a reflective electrode, and an organic light emitting element. The organic light emitting element includes an emissive material layer doped with an emissive dopant, and is disposed between the transparent electrode and the reflective electrode. The total thickness of the organic light emitting element is greater than the wavelength of the light from the emissive material layer.

This application claims the benefit of Taiwan Application Serial No. 094101891, filed Jan. 21, 2005, the subject matter of which is incorporated herein by reference.

### BACKGROUND OF THE INVENTION

(1) Field of the Invention

The invention relates to an organic light emitting device capable of reducing optical interference.

(2) Description of the Prior Art

An organic light emitting diode (OLED) is a future trends in development of a flat display for the benefit of lightness, thinness, flexibility, portability, full color, high brightness, power saving, wide viewing angle, and low image sticking. The OLED includes an inverted type and a non-inverted type. The inverted type means that a manufacturing process of the OLED initiates with forming a cathode on a substrate. Refer to FIG. 1A that shows a conventional structure of an inverted OLED. A transparent electrode 12, an electron transport layer 13, an emissive material layer (EML) 14, a hole transport layer 15, a hole injection layer 16 and a reflective electrode 17 are in order formed on a glass substrate 11. Thereinafter, all above layers formed between the transparent electrode 12 and the reflective electrode 17 are called “organic light emitting element”.

The light emitting principle of the OLED is described as follows. An external bias between the transparent electrode 12 and the reflective electrode 17 is provided to make electrons flow through the electron transport layer 13, and make holes flow through the hole injection layer 16 and hole transport layer 15. The result is that the electrons and the holes are combined with each other to generate an exciton in an organic material with light emission properties, such as the emission material layer 14. After that, the energy is released from the exciting state to the ground state. Due to the choice of the light emission material and the spin state characteristics, only 25% of the releasing energy can be applied to make the OLED emit light. The 25% of releasing energy displays in the form of light with different color according to the different band gaps of the chosen emissive materials.

The emissive material layer 14 has an upper light-emitting surface and a lower light-emitting surface. The upward light is reflected after through the hole transport layer 15 and the hole injection layer 16. The downward light emits out of the OLED 10 after through the electron transport layer 13, the transparent electrode 12 and the glass substrate 11. Refer to FIG. 1B, in theory, when the light touches the interface between these layers, a refraction and a reflection may occur simultaneously, so that an interference band is generated at infinity. In practice, the variation of the viewing angle affects the interference band sensed by an eye, and results in the color coordinates shift.

Refer to FIG. 1C, the curve a, b, c and d respectively represent the chromaticity coordinate y varies with the viewing angle when the thickness between the emissive material layer 14 and the reflective electrode 17 is 110 nm, 120 nm, 130 nm and 140 nm. When the viewing angle is between 0 and 80 degrees, the color saturation apparently increases with the thickness. Refer to FIG. 1D, the curve A shows that when the thickness is 140 nm and the viewing angle increases from 0 to 80 degree, the light intensity can be cut about 50%. The curve B shows that when the thickness is 110 nm, the light intensity can be cut about 80%. With larger viewing angle and greater thickness, the attenuation of the light intensity is lower.

To sum up, the optical interference generated in the course of the light transporting back and forth between the layers of the organic light emitting element. Specially, the optical interference can result in the light color change with the thickness when the light transports between the emissive material layer and the reflective electrode. The change includes the chromaticity coordinates, CIE 1931, shift with the viewing angle, and the light intensity change with the viewing angle. The two characteristics have different change level with the wavelength of the red, green and blue light and with the thickness of the red, green and blue OLED. The result is the white balance of the OLED shift with the viewing angle.

### SUMMARY OF THE INVENTION

Accordingly, the object of the invention is to prevent the OLED from the optical interference, specially, without additional process but by increasing the thickness between the emissive material layer and the two electrodes of the OLED.

It is another object of the present invention to improve the white balance of the OLED and the attenuation of the light intensity by reducing the optical interference.

The present invention provides an OLED includes a transparent electrode, a reflective electrode, and an organic light emitting element. The organic light emitting element is disposed between the transparent and the reflective electrode, and has at least one emissive material layer. Note that the thickness between the emissive material layer and the reflective electrode is greater than the major wavelength of light emitted by the OLED so as to avoid the optical interference.

The present invention can be applied to at least four types OLED such as a bottom emission, an inverted bottom emission, a top emission and an inverted top emission. Besides, it can be also applied to avoid the optical interference occurring between the emission material layer and the transparent.

### BRIEF DESCRIPTION OF THE DRAWINGS

The present invention will now be specified with reference to its preferred embodiment illustrated in the drawings, in which

FIG. 1A is an inverted OLED according to the related art;

FIG. 1B is a schematic diagram for illustrating the cause of the optical interference;

FIG. 1C is a diagram showing the chromaticity coordinate varied with the viewing angle under different thicknesses between the emissive material layer and the reflective electrode;

FIG. 1D is a diagram showing the light intensity varied with the viewing angle under different thicknesses between the emissive material layer and the reflective electrode;

FIG. 2 is an OLED according to the present invention;

FIG. 3 is a bottom emission OLED according to the present invention;

FIG. 4A is an inverted bottom emission OLED according to the present invention;

FIG. 4B is an inverted bottom emission OLED according to the present invention, and a hole auxiliary injection layer is disposed between the emissive material layer and the reflective electrode;

FIG. 5 is a top emission OLED according to the present invention;

FIG. 6 is an inverted top emission OLED according to the present invention;

FIG. 7A is an inverted bottom emission OLED including a 700 nm thick hole injection layer;

FIG. 7B is an inverted bottom emission OLED including a 710 nm thick hole injection layer;

FIG. 7C is an inverted bottom emission OLED including a 710 nm thick hole injection layer and a 10 nm thick CuPc layer;

FIG. 7D is a diagram showing the chromaticity coordinate varied with the viewing angle according to the OLEDs shown in FIGS. 7A-7C;

FIG. 7E is a diagram showing the light intensity varied with the viewing angle according to the OLEDs shown in FIGS. 7A-7C;

FIG. 8 is the optical simulation according to the present invention;

FIG. 9 is the comparison between the optical simulation and the measured value under 0 degree of the viewing angle.

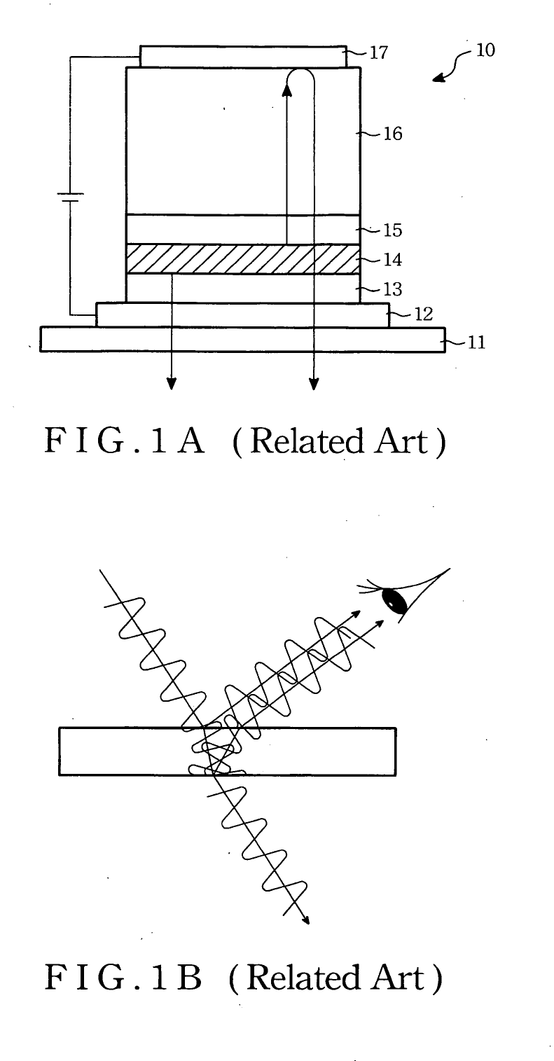

### DESCRIPTION OF THE PREFERRED EMBODIMENTS

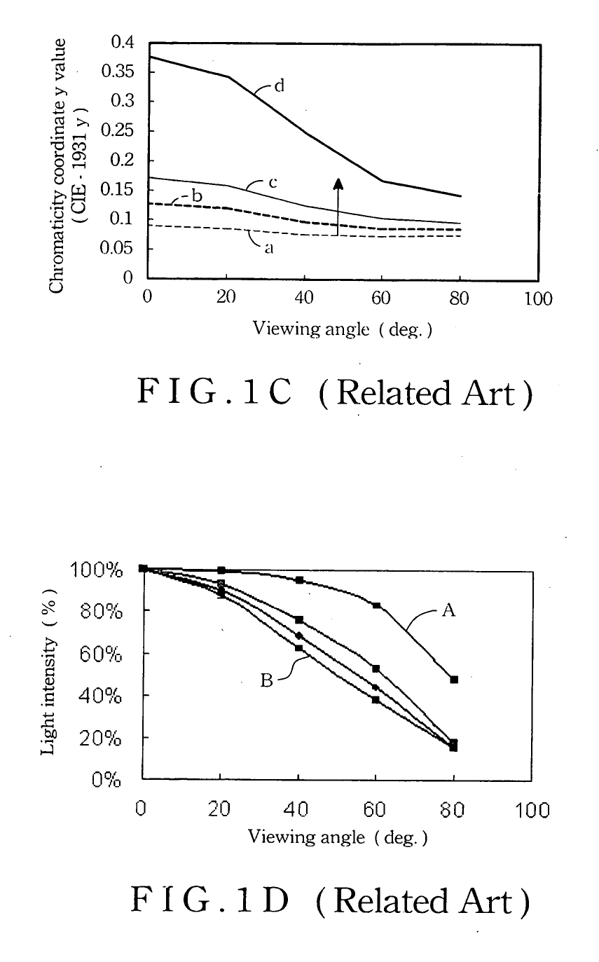

Refer to FIG. 2, the OLED 20 of the present invention includes a transparent electrode 21, a reflective electrode 22, and an organic light emitting element 23. The organic light emitting element 23 is interposed between the transparent electrode 21 and reflective electrode 22, and includes at least one emissive material layer 231 that is doped with an emissive dopant. It is emphasized that the organic light emitting element 23 has a thickness t greater than the major wavelength λ of light emitted by the OLED 20. Because the wavelength of the visible light is from 380 to 700 nm, the thickness t of the organic light emitting element 23 can be reasonably defined as 380 to 10000 nm. Under the reasonable thickness, the absorbance of the light can be also controlled.

The OLED has four types such as the bottom emission, the inverted bottom emission, the top emission and the inverted top emission. In various types of OLEDs, the reflective electrode may be taken as an anode or a cathode, and that depends on the electron transport layer or the hole transport layer forms on the reflective electrode. Similarly, the transparent electrode can also be taken as the anode or the cathode. The following diagram illustrates how to apply the present invention to the different types of OLEDs.

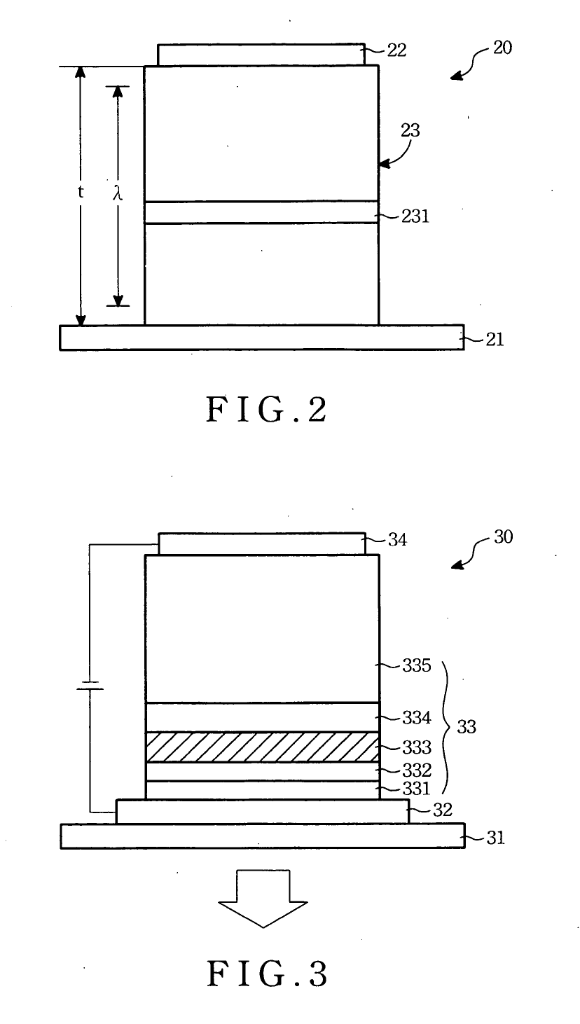

Refer to FIG. 3, a bottom emission OLED 30 according to the present invention is shown. The bottom of the substrate 31 is a light emitting surface. A transparent electrode 32 is formed on the substrate 31. An organic light emitting element 33 is formed on the transparent electrode 32. The organic light emitting element 33 includes a hole injection layer 331, a hole transport layer 332, an emissive material layer 333, an electron transport layer 334, an electron injection layer 335 stacked in order. And then, a reflective electrode 34 is formed on the organic light emitting element 33. The transparent electrode 32 compacts with the hole injection layer 331 to be taken as the anode, and the reflective electrode 34 compacts with the electron injection layer 335 to be taken as the cathode.

According to the related art, the thickness between the emissive material layer 333 and the reflective electrode 34 has considerable influence on the interference, so the thickness should be larger than the major wavelength of light emitted by the OLED 30, and is reasonably defined as 380 to 10000 nm. In this embodiment, the total thickness of the electron transport layer 334 and the electron injection layer 335 is greater than the major wavelength. For example, in a red OLED, the thickness between the emissive material layer 333 and the reflective electrode 334 should be larger than the major wavelength of the red light (about 700 nm). In a blue OLED, the thickness between the emissive material layer 333 and the reflective electrode 334 should be larger than the major wavelength of the blue light (about 464 nm). In a green OLED, the thickness between the emissive material layer 333 and the reflective electrode 334 should be larger than the major wavelength of the green light (about 524 nm). It is worth observing that the preferred thickness of the electron transport layer 334 is from 5 to 200 nm; the preferred thickness of the electron injection layer 335 is from 40 to 1000 nm. In addition, the electron injection layer 335 has the greater thickness than the major wavelength alone.

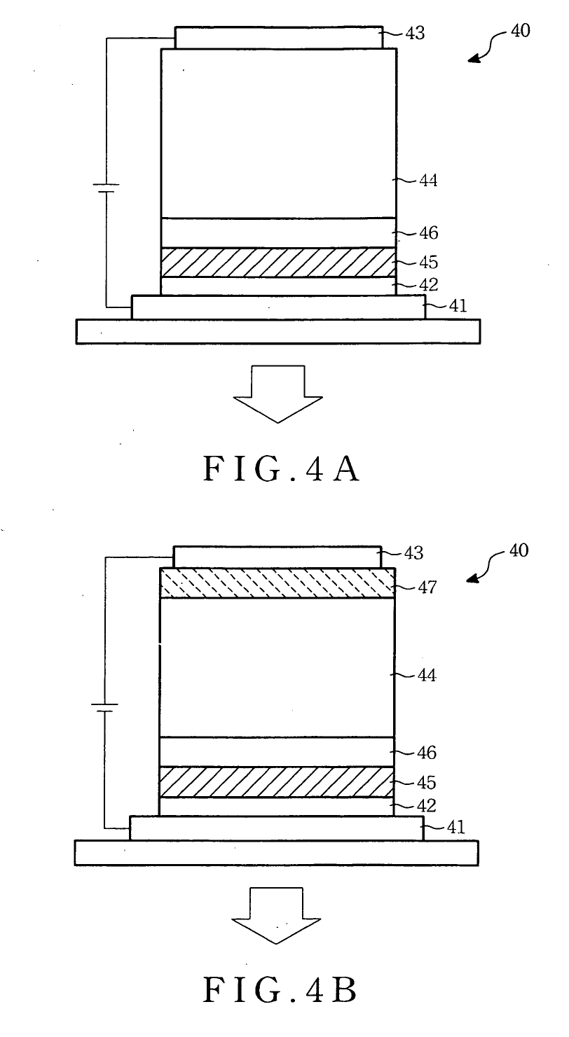

Refer to FIG. 4A, an inverted bottom emission OLED 40 according to the present invention is shown. The difference between FIG. 4A and FIG. 3 is that the transparent electrode 41 is taken as the cathode to compact with the electron transport layer 42; the reflective electrode 43 is taken as the anode to compact with the hole injection layer 44. In order to avoid the optical interference, the thickness between the emissive material layer 45 and the reflective electrode 43 should be larger than the major wavelength of light emitted by the OLED 40. Therefore, the thickness of the electron injection layer 44 should be from 40 to 1000 nm, or larger than the major wavelength. In addition, between the emissive material layer 45 and the hole injection layer 44 can be interposed a hole transport layer 46. Total thickness of the hole transport layer 46 and the hole injection layer 44 is larger than the major wavelength, or from 380 to 10000 nm. The reasonable thickness of the hole transport layer 47 is from 5 to 200 nm. In this embodiment, no electron injection layer is disposed between the transparent electrode 41 and the electron transport layer 42. In order to increase the number of the free electrons, an n-type dopant is doped in the electron transport layer 42.

Refer to FIG. 4B, between the emissive-material layer 45 and the reflective electrode 43 can be interposed a hole auxiliary injection layer 47. Preferably, the hole auxiliary injection layer 46 is disposed between the hole injection layer 44 and the reflective electrode 43. Total thickness of the hole auxiliary injection layer 47, the hole injection layer 44 and the hole transport layer 46 is larger than the major wavelength of light emitted by the OLED 40. The material of the hole auxiliary injection layer 47 has a bandgap greater than 4 eV, and it can be selected from CuPc, ITO, IZO or a semiconductor material.

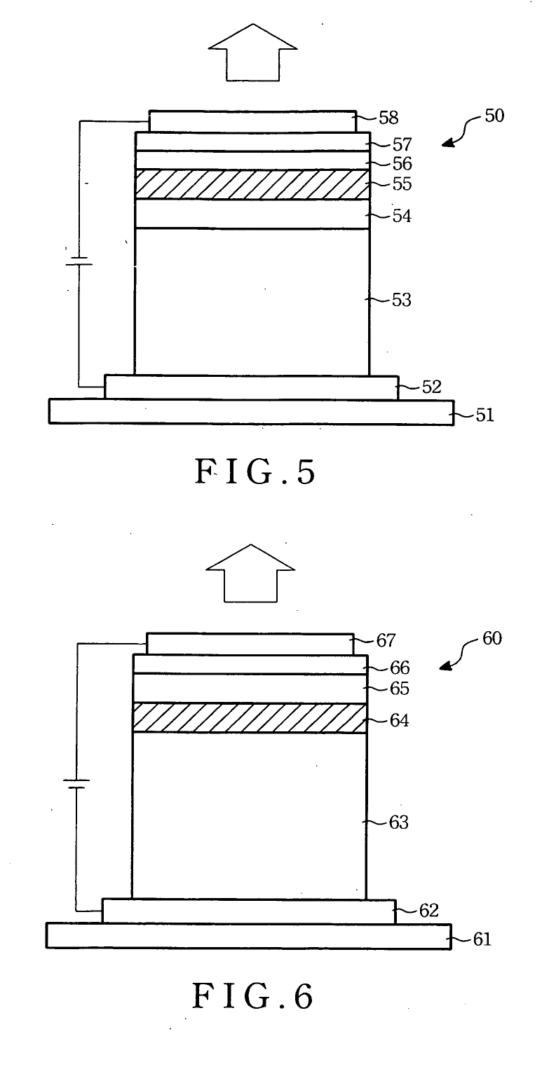

Refer to FIG. 5, a top emission OLED 50 according to the present invention is shown. A reflective electrode 52, a hole injection layer 53, a hole transport layer 54, an emissive material layer 55, an electrode transport layer 56, an electrode injection layer 57 and a transparent electrode 58 are formed in order on the substrate 51. In this embodiment, the transparent electrode 58 is taken as a cathode, and the reflective electrode 52 is taken as an anode. Between the emissive material layer 55 and the reflective layer 52 is interposed the hole injection layer 53 and the hole transport layer 54, but not interposed the electron injection layer and the electrode transport layer. As shown, the transparent electrode 58 is a light emitting surface. The same as the former two embodiments, the thickness between the emissive material layer 55 and the reflective electrode 52 still affects the interference apparently. Therefore, the thickness should be greater than the major wavelength of light emitted by the OLED 50, or from 380 to 10000 nm. Preferably, between the emissive material layer 55 and the reflective electrode 52, the hold transparent layer has a thickness of 5 to 200 nm, and the hole injection layer has a thickness of 40 to 1000 nm.

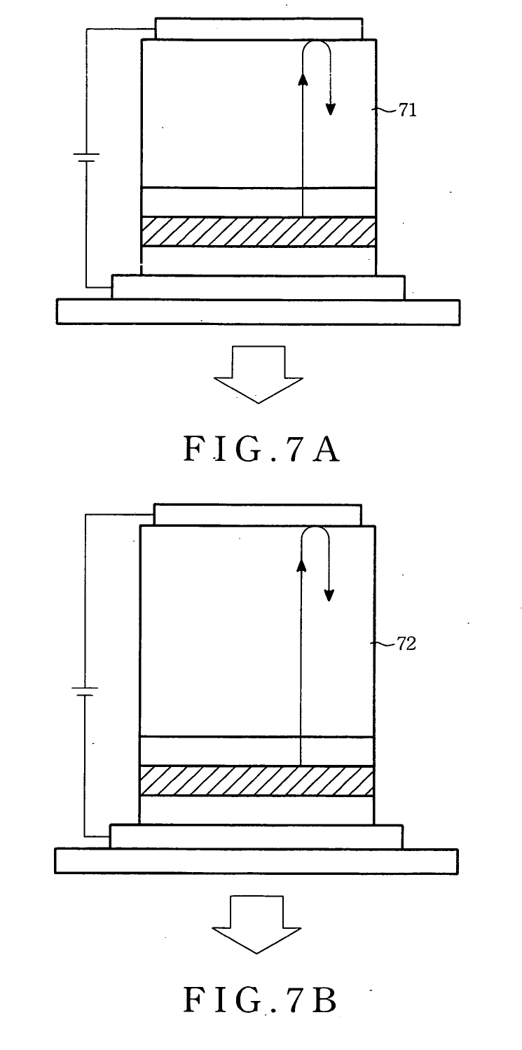

Refer to FIG. 6, an inverted top emission OLED 60 is shown. A reflective electrode 62, an electron transport layer 63, an emissive material layer 64, a hole transport layer 65, a hole injection layer 66 and a transparent electrode 67 are formed in order on a substrate 61. The electron transport layer 63 between the emissive material layer 64 and the reflective electrode 62 has a thickness greater than the major wavelength of light emitted by the OLED 60, or from 380 to 10000 nm. Besides, an electron injection layer (not shown) is interposed between the emissive material layer 64 and the electron transport layer 63 that has a thickness of 5 to 200 nm. The electron injection layer has a thickness of 40 to 1000 nm. Total thickness of the two layers should be larger than the major wavelength.

A point worth emphasizing, in FIG. 3 and FIG. 6, the hole injection layer and/or the hole transport layer can be selectively interposed between the transparent electrode 32, 67 and the emissive material layer 333, 64. The electron transport layer and/or the electron injection layer can be selectively interposed between the reflective electrode 34, 62 and the emissive material layer 333, 64. In FIGS. 4A-4B and FIG. 5, the electron injection layer and/or the electron transport layer can be selectively interposed between the transparent electrode 41, 58 and the emissive material layer 45, 55. The hole transport layer and/or the hole injection layer can be selectively interposed between the reflective electrode 43, 52 and the emissive material layer 45, 55. By the way, all above reflective electrodes are made of metal, semiconductor and the metal oxide or the conductive polymer. Specially, the metal or the semiconductor prefers the reflectance of greater than 40 percent. The hole transport layer can use NPB (N,N-di(naphthalene-1-yl)-N,N-diphenyl-benzidene).

To sum up, in all above OLEDs, the part which can apparently affect the interference is between the light emitting and the reflective electrode. That means the optical interference easily causes in the course of light emitted to the reflective electrode, and then reflected to the light emitting surface. It has nothing to do with the reflective electrode taken as the anode or the cathode. Although above embodiments are used to avoid the optical interference causing between, the emissive material layer and the reflective electrode the concept disclosed in the present invention is also adapted to the optical interference causing between the emissive material layer and the transparent electrode.

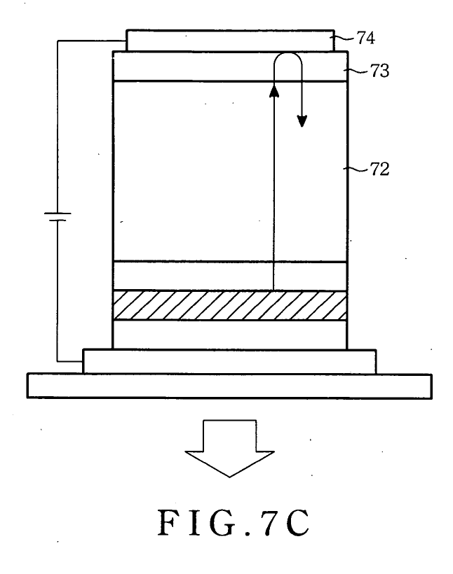

Both FIG. 7A and FIG. 7B show inverted bottom emission OLEDs, but they have different thickness in hole injection layer 71, 72. Both FIG. 7B and FIG. 7C have the same thickness in hole injection layer 72, but in FIG. 7C, a CuPc layer is interposed between the hole injection layer 72 and the reflective electrode 74, and the variation of chromaticity coordinates and light intensity are shown in FIG. 7D and FIG. 7E.

Refer to FIG. 7D, which shows the chromaticity coordinate varied with the viewing angle according to the OLEDs shown in FIGS. 7A-7C. Curve a1, b1 and c1 respectively show that the color saturation is stable when the hole injection layer 71 and 72 respectively are 700 nm and 710 nm thick under the viewing angle of 0 to 80 degree. No matter whether the CuPc layer 73 is interposed or not, the light color does not change. Under various viewing angles, the light intensity change of the OLED in the FIGS. 7A-7C is shown in FIG. 7E. Curve A1, B1, C1 indicates that the color intensity is stable below 60 degree of viewing angle. It proves that the major factor affecting the optical interference is the thickness of the organic light emitting element, but not the material. As long as the thickness of the organic light emitting element is increased, the optical interference can be improved to reduce the color shift and the attenuation of the light intensity.

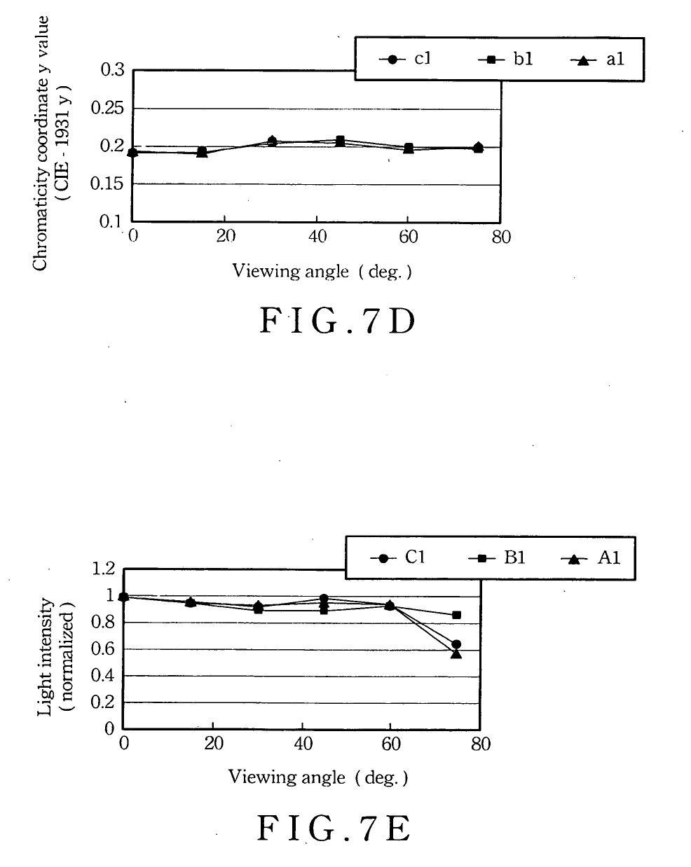

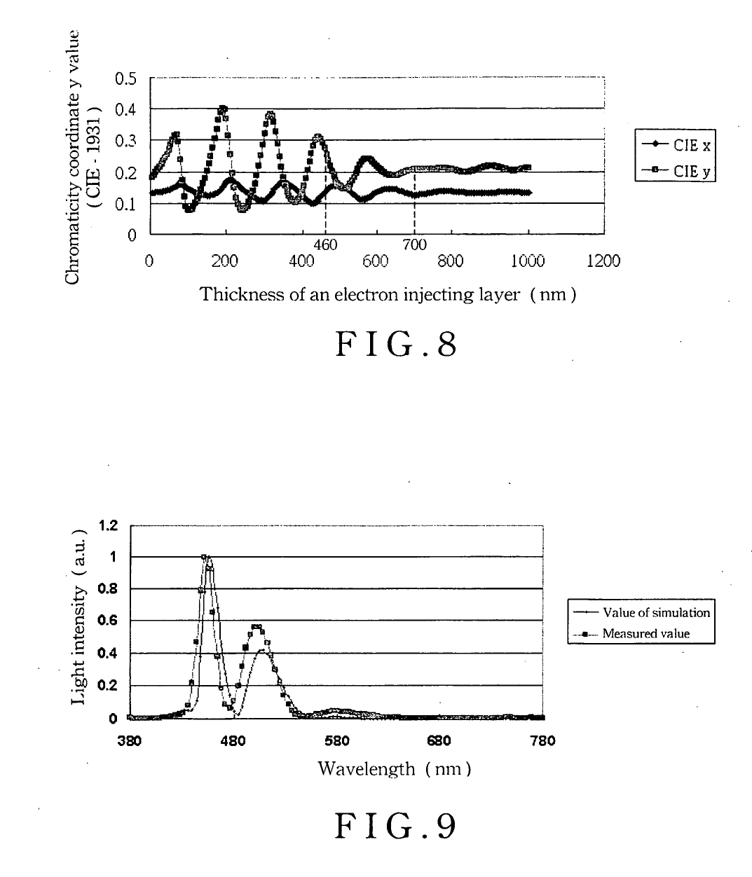

FIG. 8 shows a result of optical simulation. The ordinate is the chromaticity coordinate y value (CIE 1931); the abscissa is the thickness of the hole injection layer. While the thickness between the light emitting and the reflective electrode is larger than 464 nm, the change of the CIE value tends to relax. While the thickness reaches to 700 nm, the CIE value has been steady and smooth. It represents the optical interference has began to ease up, the serious color shift will not happen. FIG. 9 is a comparison between the optical simulation and the measured value under 0 degree of the viewing angle. In respect of the light intensity varied with the wavelength, the simulation is closed to the measured value. It illustrates the simulation is enough to prove the effect of the present invention.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. An organic light emitting device (OLED), comprising:
a transparent electrode;
a reflective electrode; and
an organic light emitting element, interposed between the transparent electrode and the reflective electrode, including an emissive material layer doped with an emission dopant and having a thickness larger than the major wavelength of light emitted by the OLED.

2. The organic light emitting device of claim 1, wherein the organic light emitting element further includes an emissive material layer, and the distance between the emissive material layer and the reflective electrode is larger than the major wavelength of light emitted by the OLED.

3. The organic light emitting device of claim 2, wherein the organic light emitting element further includes a hole injection layer interposed between the emissive material layer and the reflective electrode, and the thickness of the hole injection layer is larger than the major wavelength of light emitted by the OLED.

4. The organic light emitting device of claim 2, wherein the organic light emitting element further includes a hole transport layer and a hole injection layer interposed between the emissive material layer and the reflective electrode, and the total thickness of the hole transport layer and the hole injection layer is larger than the major wavelength of light emitted by the OLED.

5. The organic light emitting device of claim 2, wherein the organic light emitting element further includes a hole auxiliary injection layer interposed between the emissive material layer and the reflective electrode, and the material of the hole auxiliary injection layer is CuPc, ITO, IZO, or a semiconductor material.

6. The organic light emitting device of claim 2, wherein the organic light emitting element further includes a hole auxiliary injection layer interposed between the emissive material layer and the reflective electrode, and the hole auxiliary injection layer has a band gap greater than 4 eV.

7. The organic light emitting device of claim 2, wherein the organic light emitting element further includes a hole auxiliary injection layer, a hole injection layer and a hole transport layer interposed between the emissive material layer and the reflective electrode, and the total thickness of the three layers is larger than the major wavelength of light emitted by the OLED.

8. The organic light emitting device of claim 2, wherein the organic light emitting element further includes an electron injection layer interposed between the emissive material layer and the reflective electrode, and the thickness of the electron injection layer is larger than the major wavelength of light emitted by the OLED.

9. The organic light emitting device of claim 8, wherein the organic light emitting element further includes an electron transport layer interposed between the emissive material layer and the electron injection layer, and the total thickness of the electron transport layer and the electron injection layer is larger than the major wavelength of light emitted by the OLED.

10. The organic light emitting device of claim 1, wherein the material of the reflective electrode is selected from the group consisting of metal, semiconductor, metal oxide and conductive polymer.

11. An organic light emitting device, comprising:
a transparent electrode;
a reflective electrode; and
an organic light emitting element, interposed between the transparent electrode and the reflective electrode, having a thickness ranging from about 380 nm to about 10000 nm.

12. The organic light emitting device of claim 11, wherein the organic light emitting element further includes an emissive material layer, and the distance between the emissive material layer and the reflective electrode ranges from about 380 nm to about 10000 nm.

13. The organic light emitting device of claim 12, wherein the organic light emitting element further includes a hole injection layer interposed between the emissive material layer and the reflective electrode, and the thickness of the hole injection layer ranges from about 40 nm to about 1000 nm.

14. The organic light emitting device of claim 13, wherein the organic light emitting element further includes a hole transport layer interposed between the emissive material layer and the hole injection layer, and the thickness of the hole transport layer ranges from about 5 nm to about 200 nm.

15. The organic light emitting device of claim 12, wherein the organic light emitting element further includes an electron injection layer interposed between the emissive material layer and the reflective electrode, and the thickness of the electron injection layer ranges from about 40 nm to about 1000 nm.

16. The organic light emitting device of claim 15, wherein the organic light emitting element further includes an electron transport layer interposed between the emissive material layer and the electron injection layer, and the thickness of the electron transport layer ranges from about 5 nm to about 200 nm.

17. The organic light emitting device of claim 11, wherein the material of the reflective electrode is selected from the group consisting of metal, semiconductor, metal oxide and conductive polymer.
